(19) United States
(12) Patent Application Publication
(10) Pub. No.: US 2015/0355284 A1
(43) Pub. Date: Dec. 10, 2015

(54) METHOD OF USING A SYSTEM FOR STORING ELECTRICAL POWER

(71) Applicant: IFP ENERGIES NOUVELLES, Rueil-Malmaison (FR)

(72) Inventors: Eric PRADA, Lyon (FR); Domenico DI DOMENICO, Lyon (FR); Yann CREFF, Les Cotes D'arey (FR)

(21) Appl. No.: 14/758,847

(22) PCT Filed: Sep. 18, 2013
(86) PCT No.: PCT/FR2013/052146

§ 371 Date: Jul. 1, 2015

(30) Foreign Application Priority Data
Oct. 25, 2012 (FR) 1202848

(51) Int. Cl. G01R 31/36; G05B 13/04

(52) U.S. Cl. CPC G01R 31/3651; G05B 13/042

(57) ABSTRACT

The invention is a method of using a system for storing electrical power which minimizes aging of the system. An optimal profile of use is defined to minimize the aging of the system. An initial profile of use is chosen. A dynamic model of aging of the system is defined which modes the losses of electrical capacity and/or power of the system as a function of time. Next, by use of the dynamic model of aging, an aging indicator is determined for the system after this profile has been applied to the system. Last, the profile of use is modified and the step of calculating the indicator is reiterated until a minimal aging indicator is obtained. The optimal profile is then applied to the system for storing electrical power.

### CROSS REFERENCE TO RELATED APPLICATION

This application is a U.S. national phase application filed under 35 U.S.C. §371 of International Application No. PCT/FR2013/052146, filed Sep. 18, 2013, designating the United States, which claims priority from French Patent Application No. 1202848, filed Oct. 25, 2012, which are hereby incorporated herein by reference in their entirety for all purposes.

### BACKGROUND OF THE INVENTION

1. Field of the Invention

The present invention relates to systems for storing electrical power such as batteries. In particular, the invention relates to a method of using a system for storing power in which an optimal profile of use is determined for the system allowing the aging of the system to be limited.

2. Description of the Prior Art

A profile of use of a battery represents power (P) or current (I) as a function of time. It may be a question of a charging profile, a discharging profile, or of a charging and discharging profile. Such a profile is said to be optimized in the context of the invention when it allows the aging of the battery to be limited.

In the context of automotive and power generation industries that are undergoing profound changes, Li-ion battery technology has been the subject of a great deal of R&D work seeking to design robust, reliable and durable systems for electrified vehicles.

It would be desirable to increase the lifetime of Li-ion batteries as these systems represent a substantial fraction of the cost of PHEVs (plug-in hybrid electric vehicles) and EVs (electric vehicles).

Specifically, battery cost and aging must be decreased if these systems are to be used on an industrial scale. Particularly, the recharging phase of electrified vehicles has greatly limited the adoption of these novel automotive technologies. Safety, durability and charging time criteria must be met during use of the vehicle.

For reasons of practicality of use, recharging time must be optimized for the user while ensuring the durability and safe operation of the system for storing electrical power.

It is therefore necessary to define for each battery an optimized profile of use (charging/discharging profile), that is a profile allowing aging of the battery to be slowed.

To do this, a recharging strategy is adjusted on the basis of a mathematical model of the aging, in order to decrease degradation effects while recharging.

Methods that use generic behavioral models of the aging of Li-ion systems are known. These models are either based on empirically obtained maps, or on static empirical models that take into account the impact of stress factors on aging. Such techniques are described in the following documents:

A. Hoke, A. Brisette, D. Maksimovic, A. Pratt, K. Smith, Vehicle Power Propulsion Conference, (2011).

B. Lunz, H. Walz, D. U. Sauer, Vehicle Power Propulsion Conference, (2011).

These models are then coupled to optimization algorithms that are intended to find the optimal profile of use by minimizing a cost function defined using indicators of the level of aging of the system. These indicators are generally calculated using a mathematical model of aging.

Regarding research relating to charging/discharging profiles, reference is also be made to the method described in:

A. Hoke, A. Brisette, D. Maksimovic, A. Pratt, K. Smith, Vehicle Power Propulsion Conference, (2011).

This static approach to the modeling of aging is based on static, semi-empirical models whereas the second group adopted a simplified isothermal single-particle type physical approach. In their work, Hoke et al. optimize charging of an electrical vehicle over a period of 24 hours starting with an initial SOC of about 30%. Their optimization results tend to show that it would be preferable to delay the charging and apply increasing powers (in the form of a ramp).

Various patent applications (US 2006/0071634, US 2005/0156577, EP 2 193 587, US 2009/0208817) address the problem of Li-ion battery chargers. These chargers may have various charging profile functionalities, such as the application of pulsed current, and may make use of various strategies to optimize the usable power or lifetime of the system. These management strategies are either preset or adaptive. Recharging algorithms based on physical models that take into account certain aging indicators are also known.

However, these models are static in nature and are therefore not very predictive as regards dynamic effects.

### SUMMARY OF THE INVENTION

Thus, the subject matter of the invention is a method for defining an optimal profile of use for a system for storing electrical power, allowing the aging of the system to be minimized by a dynamic model of aging of the system. This dynamic character allows the losses of electrical capacity and/or power of the system to be modeled as a function of time, in contrast to the static models of the prior art.

This method makes possible accounting for thermal and electrical transients and the initial state of aging into account. This leads to results that are more precise. In addition, this method allows, relative to use of a static model, a broader and more realistic spectrum of charging profiles to be tested.

### THE METHOD TO THE INVENTION

The invention relates to a method of using a system for storing electrical power. The system comprises a positive electrode, a negative electrode and an electrolyte, wherein:
an optimal profile of use is defined for the system allowing the aging of the system to be minimized. The optimal profile of use is defined by carrying out the steps of:
   i) choosing an initial profile of use;
   ii) defining a dynamic model of aging of the system modeling losses of electrical capacity and/or power of the system, the model being a dynamic model of the losses as a function of time which accounts for an initial aging state of the system before the initial profile of use has been applied;
   iii) determining an aging indicator for the system after the initial profile of use has been applied to the system, by the dynamic model of aging; and
   iv) modifying the initial profile of use and reiterating step iii) until a minimal aging indicator is obtained;
and the optimal profile is applied to the system.

According to the invention, the dynamic model of aging may account for an impact of the profile of use on the system throughout the profile of use.

The dynamic model of aging may describe losses of electrical capacity and/or power of the system as a function of operational current, temperature, state of charge (SOC) and depth of discharge (DOD) factors.

The dynamic model of aging may reproduce the dynamic electrochemical and thermal behavior of the system by modeling the electrode degradation mechanisms leading to a loss of capacity and a loss of power.

According to one embodiment, the dynamic model of aging comprises:
a model describing changes in a layer of particles formed on the surface of an electrode;
a model describing that the thickness of the layer increases by consuming active species; and
a model describing that molecules of the electrolyte reduce at an interface between an electrode and the layer after having passed through the layer by diffusion and convection.

The profile of use may be a current profile or a power profile.

The profile of use may be a charging profile of the system or a discharging profile of the system, or a profile corresponding to a series of charges and discharges.

The system for storing electrical power may be a Li-ion, or Ni-MH, or Pb-acid battery or an ultracapacitor.

According to the invention, the aging indicator may be a loss of electrical capacity or a loss of power.

The profile of use may be modified until a minimal aging indicator is obtained by use of a constrained optimization algorithm.

### BRIEF DESCRIPTION OF THE INVENTION

Other features and advantages of the method according to the invention will become more apparent on reading the following description of nonlimiting example embodiments, given with reference to the appended figures described below.

### BRIEF DESCRIPTION OF THE DRAWINGS

FIG. 1A shows a standard profile of current use for an electric vehicle;

FIG. 1B shows the variation (as a function of time t) of the state of charge (SOC) of the battery over a day, after application of the profile in FIG. 1A;

FIG. 2 depicts the steps used to establish the optimal profile of use according to the invention;

FIG. 3 is a schematic representation of the layer of particles (SEI) formed on the surface of an electrode;

FIG. 4 illustrates the losses of capacity (PC) after 1800 CC charges at various C-Rates as a function of the type of cooling;

FIG. 5 illustrates a charging profile optimization result obtained by use of the method according to the invention. It is a question of an optimal current profile; and

FIG. 6 illustrates a charging profile optimization result obtained by use of the method according to the invention. It is a question of an optimal current profile.

### DETAILED DESCRIPTION OF THE INVENTION

The invention relates to a method of using a system for storing electrical power, such as a battery, in which an optimized profile of use of the system is established allowing the aging of the system to be limited.

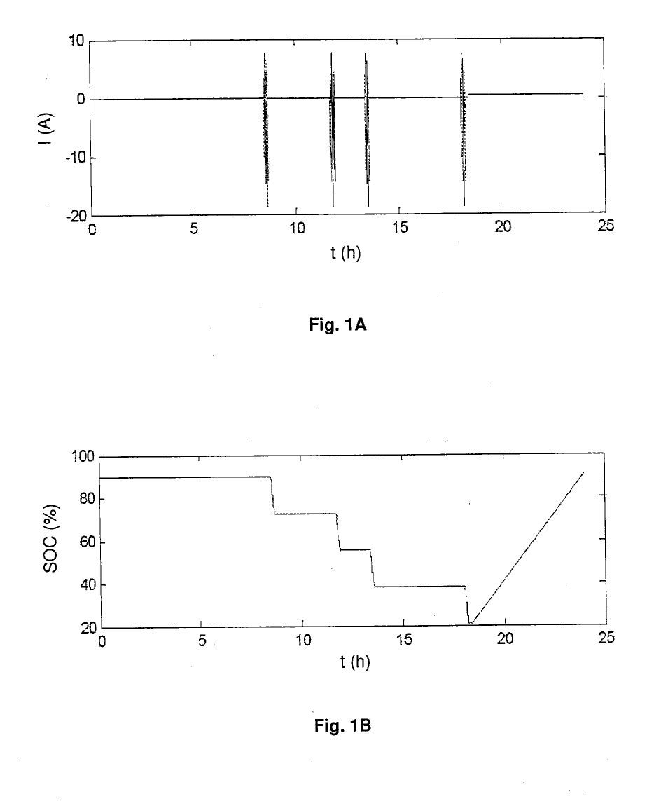

A profile of use of a battery represents power (P) or current (I) as a function of time. It may be a question of a charging profile, a discharging profile, or a charging and discharging profile. Such a profile is optimized, when in the context of the invention, it allows the aging of the battery to be limited. FIG. 1A shows a standard profile of current use for an electric vehicle. I represents the current in amperes, and t represents the time in hours. Four driving phases (corresponding to trips made by a driver) are interrupted by phases of rest (parking) that could be used for V2G (vehicle to grid) applications. The last phase, in which the state of charge (SOC) increases (See FIG. 1B), corresponds to the recharging of the vehicle.

The invention is described by way of one particular example embodiment, corresponding to an optimization of a charging current (I) profile. It is therefore a question of determining a profile representing the current (I) as a function of time that minimizes the aging of the battery once the latter has been charged.

Likewise, the invention applies to a discharging profile. In this case, a profile is determined representing the current (I) or power (P) as a function of time that minimizes the aging of the battery once the latter has been discharged.

Likewise, the invention applies to a charging and discharging profile. In this case, a profile is determined representing the current (I) or power (P) as a function of time that minimizes the aging of the battery once the latter has undergone one or more cycles of charging and discharging.

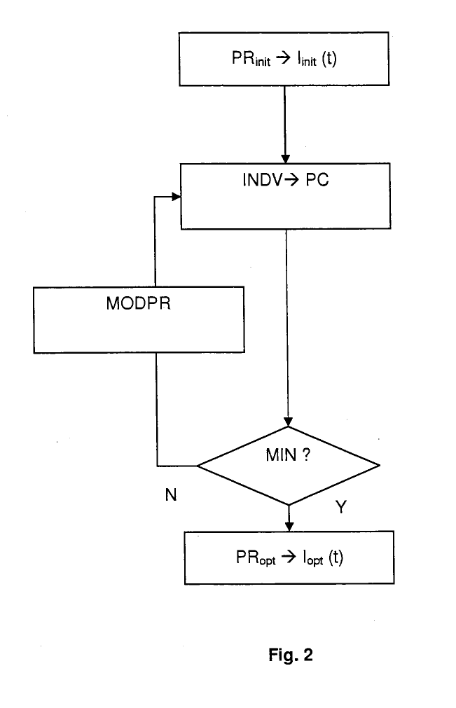

The optimal profile of use according to the invention is established using steps that include the following steps of (FIG. 2):
1. choosing an initial charging profile (PRᵢₙᵢₜ);
2. determining an aging indicator (INDV) for the battery as a function of the charging profile; and
3. modifying the charging profile until a minimal aging indicator (MODPR) is obtained.

### 1. Choosing an Initial Profile of Use (PRᵢₙᵢₜ)

A profile of use as a function of time to be applied to the system is defined.

For the chosen example, a current charging profile I(t) representing the current (I) as a function of time (t) to be applied to the system to recharge it, is defined. This initial profile is denoted Iᵢₙᵢₜ(t).

Advantageously, this profile is defined as being a constant current charging protocol, allowing the battery to be charged in n hours.

Next, the aging of the system induced by applying this profile to the system is calculated. Next, the profile is modified until a minimal aging is obtained.

### 2. Determining an Aging Indicator (INDV) for the Battery as a Function of the Profile

According to the invention, an aging indicator is dynamically determined for the battery as a function of the profile I(t).

A model of aging is a model capable of predicting the losses of electrical capacity and/or power of a battery element as a function, for example, of operational current, temperature, state of charge (SOC) and depth of discharge (DOD) factors.

According to the invention, the model reproduces the dynamic electrochemical, and possibly thermal, behavior of the battery by modeling the electrode degradation mechanisms leading to a loss of capacity and a loss of power. This model models physico-chemical and thermal effects at the micro and macroscopic scale.

The model according to the invention is dynamic because it takes into account the history of the battery. That is it takes into account everything that has happened to the battery before application of the charging profile I(t) and everything that happens to the battery between the start and the end of application of the charging profile I(t).

To do this, a model of aging is used that takes into account an initial aging state of the battery and the notion of time during the profile, in contrast to the static models of the prior art.

Thus, the initial state of the model contains the operational history of the cell. That is everything that has happened before and during application of the charging profile. The final aging state thus depends on the initial state of the battery and on everything that is applied to the battery during the application of the profile.

Thus, a dynamic model of aging is defined for the battery, which models the losses of electrical capacity and/or power of the battery as a function of time.

The model of aging especially comprises:
a model describing changes in a layer of particles formed on the surface of an electrode;
a model describing that the thickness of the layer increases by consuming active species; and
a model describing that solvent molecules reduce at the interface between an electrode and the layer after having passed through the layer by diffusion/convection.

According to one embodiment, this model is constructed for the LiFePO₄/graphite Li-ion system. The invention is also applicable to Ni-MH, ultracapacitor and Pb-acid systems. These systems are characterized by the presence of:
1 positive electrode that stores the active species (Li⁺, Na⁺, H⁺, etc.);
1 negative electrode that stores the active species (Li⁺, Na⁺, H⁺, etc.);
1 separator for electrically insulating the 2 electrodes; and
1 electrolyte for enabling ion exchange, consisting of a solvent and salt.

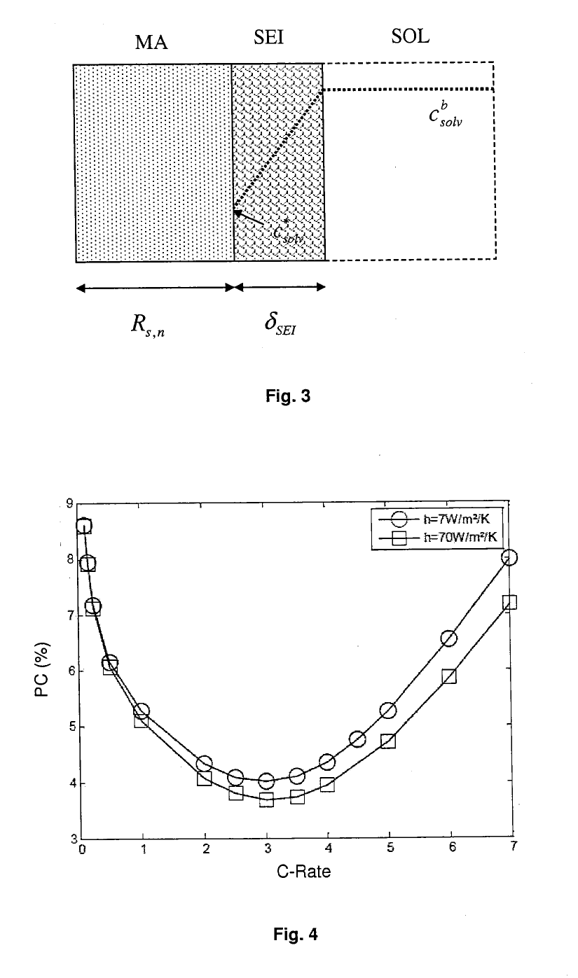

Li-ion batteries are systems composed of a porous positive electrode and a porous negative electrode separated by a porous medium that is electronically insulating but that allows Li⁺ ions to pass from one electrode to another during charging or discharging phases. The pores of the three compartments are filled with a generally liquid electrolytic phase. FIG. 3 is a schematic representation of the layer of particles (SEI) formed on the surface of an electrode (active material of the negative electrode), in which:
MA is the active material;
SOL is the solution (electrolytic phase); and
SEI is the amorphous porous polymer layer (˜100 nm).

The electrochemical reactions that store electrical power during charging of the accumulator may be represented by the following equations, equations 1 and 2.

For the positive electrode:

$${LiFePO}_{4} {\to }^{Charge} {yLi}^{+} + {ye}^{-} + {Li}_{1 - y} {FePO}_{4} . \qquad ( 1 )$$

For the negative electrode:

$${xLi}^{+} + {xe}^{-} + {Li}_{1 - x} {C}_{6} {\to }^{Charge} {LiC}_{6} . \qquad ( 2 )$$

During phases of discharging of the accumulator, the reactions are reversed.

A model of aging allows both losses of capacity and power to be modeled. According to one example, this model assumes that the source of aging is consumption of cyclable lithium (Li⁺) via reduction of the solvent (S) at the negative electrode (3). It will be noted that for other systems, the aging process may be due to oxidation of the solvent at the positive electrode.

The layer of particles formed on the surface of the negative electrode is referred to as an SEI (solid electrolyte interphase).

The SEI will continually grow throughout the lifetime of the battery and will both consume active species (loss of capacity) and increase the electrical resistance of the battery (loss of power). A schematic representation of the surface SEI of particles on the negative electrode is illustrated in FIG. 3.

As illustrated in FIG. 3, the SEI is a complex medium that may be modeled as a thick porous polymeric layer (˜100 nm). Solvent molecules will reduce at the negative electrode/SEI interface (equations 3, 4 and 5 in Table 1) after having passed through the SEI layer by diffusion/convection (Equation 6). As the thickness of the SEI increases (Equation 7), the porosity of the negative electrode decreases (Equation 8). Under the aforementioned hypothesis regarding the aging mechanism, it is possible to define a critical SEI thickness corresponding to complete blockage of the porosity of the electrode (Equation 9). The decrease in the porosity of the negative electrode will lead to an increase in the impedance of the system via modification of the effective transport properties of the Li⁺ ions in the electrolytic phase (Equation 10). Growth of the SEI layer will also have an impact on the resistance R_{SC} (defined by Equation 11).

One example model is described below (Table 1, and Table 2 with respect to thermal mechanisms). The temperature of the system is a preponderant factor in the activation of the electrical behavior of the storage system. This model is a physical, electrochemical and thermal model of a Li-ion system in LiFePO₄/graphite technology.

TABLE 1
Equations of the dynamic model of aging

| Mechanism of growth of the SEI layer by diffusion of the solvent | | | Boundary |
|---|---|---|---|
| and modification of the porosity of the negative electrode | | Eq | conditions |
| Reduction | S + 2e⁻ + 2Li⁺ → P | (3) | |
| reaction of the | | | |
| solvent at the | | | |
| negative | | | |
| electrode | | | |
| Tafel kinetics of the reduction | ${i}_{s} = - {i}_{s}^{0} exp ( \frac{βF}{RT} \frac{{δ}_{SEI}}{{κ}_{SEI}} \frac{I}{{S}_{n}} ) exp ( - \frac{βF}{RT} ( {φ}_{s , n} - {U}_{s} ) ) exp ( \frac{- {E}_{a , k}}{R} ( \frac{1}{{T}_{int}} - \frac{1}{{T}_{ref}} ) )$ | (4) | |
| reaction of the | | | |
| solvent | | | |
| Equation of | iₜ = iᵢₙₜ + iₛ | | |
| conservation of | | | |
| current | | | |
| Mass balance for the solvent | $\frac{\partial }{\partial t} {C}_{solvent} = {D}_{solvent} \frac{{\partial }^{2}}{\partial {r}^{2}} {C}_{solvent} - \frac{d}{dt} {δ}_{SEI} \frac{\partial }{\partial r} {C}_{solvent}$ | (6) | $\begin{matrix}- {D}_{solvent} \frac{\partial }{\partial r} {C}_{solvent} {\vert}_{r = {R}_{s , n}} \\ + \frac{d}{dt} {δ}_{SEI} {C}_{solvent} {\vert}_{r = {R}_{s , n}} = \frac{{i}_{s}}{F} \\ {C}_{solvent} {\vert}_{r = {R}_{s , n} + {δ}_{SEI}} = {ɛ}_{SEI} {C}_{solvent}^{bulk}\end{matrix}$ |
| Growth rate of the SEI | $\frac{d}{dt} {δ}_{SEI} = - \frac{{i}_{s} {M}_{SEI}}{2 F {ρ}_{SEI}}$ | (7) | |
| Porosity modification | $\frac{d}{dt} {ɛ}_{e , n} = - \frac{3 {ɛ}_{s , n}}{{R}_{s , n}} \frac{d}{dt} {δ}_{SEI} = + \frac{{i}_{s} {M}_{SEI}}{2 F {ρ}_{SEI}} \frac{3 {ɛ}_{s , n}}{{R}_{s , n}}$ | (8) | |
| Critical thickness of the SEI | ${δ}_{SEI}^{c} = ( \frac{1 - {ɛ}_{f , n}}{{ɛ}_{s , n}} - 1 ) \frac{{R}_{s , n}}{3}$ | (9) | |
| Variation of ohmic resistance during aging | ${R}_{ohm} ( t ) = \frac{1}{2 A} ( \frac{{δ}_{n}}{κ ( {c}_{e} ) {\{ 1 - {ɛ}_{s , n} ( 1 + \frac{3 {δ}_{SEI} ( t )}{{R}_{s , n}} ) \}}^{Brugg , n}} + 2 \frac{{δ}_{sep}}{{κ}_{sep}^{eff}} + \frac{{δ}_{p}}{{κ}_{p}^{eff}} )$ | (10) | |
| Variation of the half-circle | ${R}_{SC} = {R}_{ct}^{p} + {R}_{ct}^{n} + {R}_{SEI}^{n} = \frac{RT}{{Fi}_{0}^{p} {S}_{p}} + \frac{RT}{{Fi}_{0}^{n} {S}_{n}} + \frac{{δ}_{SEI}}{{κ}_{SEI} {S}_{n}}$ | (11) | |
| resistance | | | |
| defined by | | | |
| impedometry | | | |

TABLE 2

| | |
|---|---|
| Heat transfer and energy balance | Eq. |

Equations of the thermal model of the dynamic model of aging

| | | |
|---|---|---|
| Energy balance | $\frac{d}{dt} T = \frac{1}{{MC}_{p}} ( {ϕ}_{gen} - {ϕ}_{tra} )$ | (12) |
| Heat flux generated during use of the | ${ϕ}_{gen} = - ( ( V - ( {U}_{p} - {U}_{n} ) ) I + T \frac{d ( {U}_{p} - {U}_{n} )}{dT} I )$ | (13) |
| battery | | |
| Heat flux transferred | φₜᵣₐ = h_{conv}A_{cell}(T − T_{amb}) | (14) |
| to the environment | | |

Coupling of the electrochemical aging model and the thermal model

| | | |
|---|---|---|
| Arrhenius law applied to the mass transport | $Ψ = {Ψ}_{ref} exp ( \frac{{E}_{a} ( Ψ )}{R} ( \frac{1}{{T}_{ref}} - \frac{1 T}{T} ) )$ | (15) |
| parameters and to the | | |
| kinetic parameters Ψ | | |

Where:
A is the geometric area of the electrodes (m²).
A_{cell} is the external area of the battery (m²).
cₑ is the Lithium concentration in the electrolytic phase (mol m⁻³).
C*ₛₒₗᵥₑₙₜ is the Lithium concentration at the electrode/SEI interface (mol m⁻³).
Cₛₒₗᵥₑₙₜ^{b} is U Lithium concentration at the electrolyte/SEI interface (mol m⁻³).
Eₐ is the activation energy (J mol⁻¹).
F is the Faraday constant (C mol⁻¹).
h is the heat exchange coefficient (W.k⁻¹.m²).
i₀ is the electron exchange current density (A m⁻²).
I is the magnitude of the current passing through the cell (A).
M_{SEI} is the molar mass of the SEI (kg.mol⁻¹).
Qₛ is the residual capacity of an electrode (Ah).
r is the radial coordinate in the 1D model.
R is the Ideal gas constant (8.314 J mol⁻¹ K⁻¹).
Rₒₕₘ is the ohmic resistance (□).
R_{SEI} is the resistance of the SEI (□).
Rₛ is the radius of the particles of active material (m).
S relates to the solvent or to specific surface area.
t is time (s).
U is thermodynamic potential (V).
β is the coefficient of charge transfer.
δ is the thickness of the electrodes and/or separator (m).
δ_{SEI} is the thickness of the SEI (m).
εₑ is the fraction per unit volume of electrolyte.
εₛ is the fraction per unit volume of active material.
ε_{f} is the fraction per unit volume of binder.
ρ_{SEI} is the density of the SEI (kg.m⁻³).
κ is the ionic conductivity of the SEI (S m⁻¹).
φ is the Heat flux (W).
amb is the ambient (temperature).
Brugg is the Bruggeman coefficient.
ct relates to charge transfer.
c relates to the critical SEI thickness.
e relate to the electrolyte.
eff relate to effective properties.
D relates to diffusion.
gen relates to the heat flux generated during use of the battery.
Int relates to intercalation reactions.
n is the negative electrode.
p is the positive electrode.
ref is the reference temperature.
SEI relates to the SEI.
solvent relates to the solvent.
tra relates to the heat flux transferred to the environment.

Thus, by applying the dynamic model of aging, the loss of capacity (PC) or the loss of power of the system between the start and end of the profile of use is determined, while allowance is made for variations and the impact of the profile between the start and end of the profile.

The dynamic variation in the residual capacity of the battery Qs during the aging is calculated as:

$$\frac{d}{d t} {Q}_{s} = {i}_{s} {S}_{n}$$

The losses of capacity or power of the system are an indicator of the aging of the system after it has been subjected to the profile of use.

The following step modifies the profile to minimize this indicator, while meeting a number of constraints.

### 3. Modifying the Charging Profile Until a Minimal Aging Indicator (MODPR) is Obtained

The method according to the invention is based on a constrained optimization method.

This method allows the profile of use that minimizes the aging indicator to be determined while a number of constraints are met. This optimal profile is denoted PRₒₚₜ(t). In the case of a current profile: Iₒₚₜ(t).

These constraints are chosen in order to ensure the desired charge. They may be:
the value of the integral of the charging profile, set so that this value is equal to the capacity/power required to reach the specified charging state;
an upper bound (ub) constraint on the maximum charging current/power which ensures that the power at no time exceeds a set maximum value;
the capacity/power required for the desired charge;
etc.

Genetic algorithms are known as constrained optimization algorithms.

The constrained optimization function fmincon in Matlab®/Simulink® may also be used.

Generally, fmincon is used to find solutions to the following type of problem:

$${min}_{x} f ( x ) such that \{ \begin{matrix}c ( x ) \leq 0 \\ {c}_{eq} ( x ) = 0 \\ Ax \leq b \\ {A}_{eq} x = b \\ lb \leq x \leq ub\end{matrix}$$

Such an optimization is achieved by way of the calculation, by finite differences from a given point x₀, of the Hessian of the associated Lagrangian L:

L(x, λ, μ)=f(x)+λc(x)+μc(x)

According to the method:
the variable x represents the profile of use which is opportunely discretized with constant plateaus of fixed duration;
c(x)<0 represents a non-linear inequality constraint;
c_{eq}(x)=0 represents a non-linear equality constraint;
Ax<b represents a linear inequality constraint;
A_{eq}=b represents a linear equality constraint, used here to set the desired power;
the variable lb represents the lower limit of the current or power values;
the variable ub represents the upper limit of the current or power values; and
the variable f to be minimized is an indicator of the state of health (SOH) of the system. It may for example be a question of the loss of capacity of the battery.

The variable f is calculated as a function of the current/power profile by use of a Simulink® model of a battery cell (MSP).

The independent variable P/I (power/current) that has N current/power plateaus Iᵢ/Pᵢ each of length Δt. The maximum current is set to Iₘₐₓ whereas the maximum power Pₘₐₓ may be set to the power of the charger.

The constraint A_{eq}x=b is used to set the capacity/power required for the desired recharge, that is ΔtΣIᵢ=ΔAh_{rech} or ΔtΣPᵢ=ΔE_{rech}, where:
□Ah_{rech} is the amount of charge that is desired to be stored in the cell; and
□E_{rech} is the amount of power that is desired to be stored in the cell.

### Uses of the Method

In a first example, the method according to the invention was used to investigate and define constant current (CC) charging profiles. This type of profile is conventionally used on the industrial scale.

Regarding the impact of the current on the lifetime of a battery, it is generally accepted that large charging currents (C-Rate) greatly decrease the lifetime of the system such that the more rapid the charging regime, the shorter the lifetime of the battery. A model of aging calibrated for a 2.3 Ah LFP/graphite technology was used here to investigate and quantify the impact of the charging regime on the lifetime of the battery. Assuming a unitary charge per day of 30% to 100% SOC, various current levels were tested by simulation as illustrated in FIG. 4. FIG. 4 illustrates the losses of capacity (PC) after 1800 CC charges at various C-Rates as a function of the type of cooling h.

FIG. 4 shows a result that runs counter to the specifications generally expected for battery recharging in automotive applications. The presence of an optimum at about 3 C shows that it would be possible to charge the battery in 20 min while minimizing the loss of capacity of the system. Too slow a charge (C/8: “normal” charge in 8 h) or in contrast too rapid a charge (7 C: charge in 8.5 min) would double the aging of this Li-ion battery technology.

In a second example, the method according to the invention was used to define an optimal recharging current profile allowing the aging of the system to be minimized.

The initial profile (step 1 of the method) was a charge at constant current allowing the battery to be charged in 8 hours. The integral of the charging profile (current) over the 8 hours of charging was set equal to the capacity required for the state of charge to reach a final value of 95%, given an initial SOC of 30%. During the last two hours, recharging was not permitted in order to ensure thermal relaxation. Each hour was “cut” into intervals of 10 min.

The method was applied with the model described in Table 1.

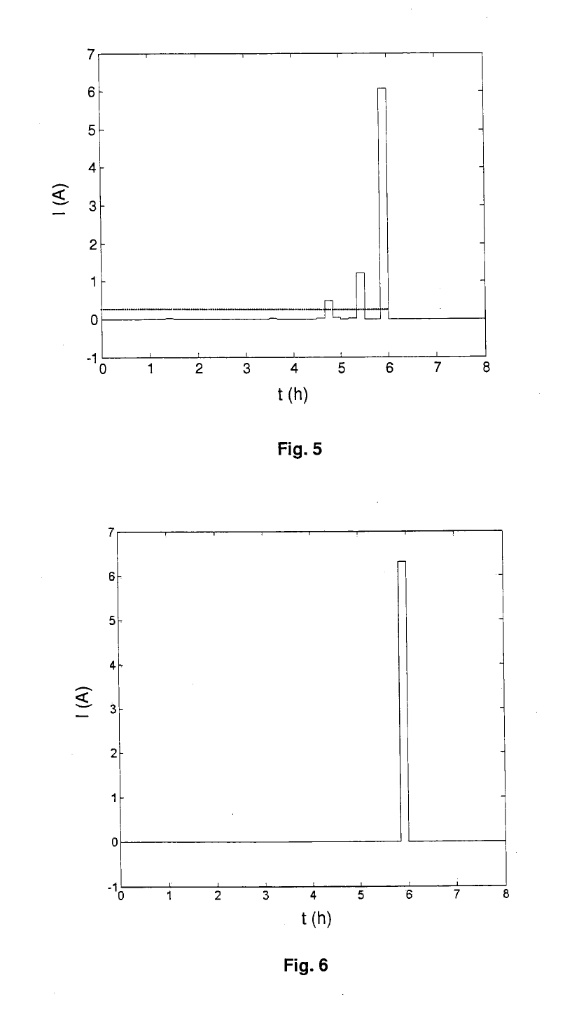

FIG. 5 shows the charging profile optimization result obtained by the method according to the invention.

It is a question of an optimal current profile (solid line). The initial profile is represented by a dotted line.

The first result illustrated in FIG. 5 shows that it is preferable to recharge the battery “as late as possible”. This is due to the fact that this limits the time the system spends in high states of charge. It is known from the literature that high SOCs accelerate the aging of battery systems.

A second very interesting result is that the observed charging is pulsed. This result is due to the fact that the model incorporates the effect of diffusion in the electrodes and in the electrolyte. It has been shown in the literature that using pulsed signals may have advantageous effects on the lifetime of Li-ion batteries.

A third result relates to the value of the last charging pulse. This last pulse has a value of 6.1 A. This value is very close to the 3C regime for which an optimum was found by simulation (FIG. 4) in the first example. Most of the recharging occurs during this last pulse.

### Advantages

The method according to the invention is adaptive as illustrated in FIGS. 5 and 6. Specifically, the optimal profile differs depending on the initial state of charge of the battery.

FIG. 6 illustrates a charging profile optimization result obtained by the method according to the invention. It is a question of an optical current profile.

The profile in FIG. 5 is obtained by applying the charging profile to a battery the initial SOH of which is 100%. The SOH is the indicator of the state of health of the system.

The profile in FIG. 6 is obtained by applying the charging profile to a battery the initial SOH of which is 80%.

The method according to the invention therefore makes it possible to take thermal and electrical transients and the initial state of aging into account, this leading to results that are more precise.

In addition, the method according to the invention leads to charging that is pulsed in character being obtained.

1-10. (canceled)

11. A method of using a system for storing electrical power, which include a positive electrode, a negative electrode and an electrolyte,
In which an optimal profile of use for the system allowing the aging of the system to be minimized is defined by the steps comprising:
i) choosing an initial profile of use;
ii) defining a dynamic model of aging of the system which models losses of electrical capacity and/or power of the system, the model being a dynamic model modeling the losses as a function of time and which accounts for an initial aging state of the system before the initial profile of use has been applied;
iii) determining an aging indicator for the system after the initial profile of use has been applied to the system, by use of the dynamic model of aging; and
iv) modifying the initial profile of use and reiterating step iii) until a minimal aging indicator is obtained; and
applying the optimal profile to the system.

12. A method according to claim 11, wherein the dynamic model of aging accounts for an impact of the profile of use on the system throughout the profile of use.

13. A method according to claim 11, wherein the dynamic model of aging accounts for losses of electrical capacity and/or power of the system as a function of operational current, temperature, state of charge and depth of discharge factors.

14. A method according to claim 12, wherein the dynamic model of aging accounts for losses of electrical capacity and/or power of the system as a function of operational current, temperature, state of charge and depth of discharge factors.

15. A method according to claim 11, wherein the dynamic model of aging reproduces dynamic electrochemical and thermal behavior of the system by modeling the electrode degradation mechanisms leading to a loss of capacity and a loss of power.

16. A method according to claim 12, wherein the dynamic model of aging reproduces dynamic electrochemical and thermal behavior of the system by modeling the electrode degradation mechanisms leading to a loss of capacity and a loss of power.

17. A method according to claim 13, wherein the dynamic model of aging reproduces dynamic electrochemical and thermal behavior of the system by modeling the electrode degradation mechanisms leading to a loss of capacity and a loss of power.

18. A method according to claim 14, wherein the dynamic model of aging reproduces dynamic electrochemical and thermal behavior of the system by modeling the electrode degradation mechanisms leading to a loss of capacity and a loss of power.

19. A method according to claim 15, wherein the dynamic model of aging comprises:
a model describing changes in a layer of particles formed on the surface of an electrode;
a model describing that thickness of the layer increases by consuming active species; and
a model describing that molecules of the electrolyte reduce at an interface between an electrode and the layer after having passed through the layer by diffusion and convection.

20. A method according to claim 16, wherein the dynamic model of aging comprises:
a model describing changes in a layer of particles formed on the surface of an electrode;
a model describing that thickness of the layer increases by consuming active species; and
a model describing that molecules of the electrolyte reduce at an interface between an electrode and the layer after having passed through the layer by diffusion and convection.

21. A method according to claim 17, wherein the dynamic model of aging comprises:
a model describing changes in a layer of particles formed on the surface of an electrode;
a model describing that thickness of the layer increases by consuming active species; and
a model describing that molecules of the electrolyte reduce at an interface between an electrode and the layer after having passed through the layer by diffusion and convection.

23. A method according to claim 18, wherein the dynamic model of aging comprises:
a model describing changes in a layer of particles formed on the surface of an electrode;
a model describing that thickness of the layer increases by consuming active species; and
a model describing that molecules of the electrolyte reduce at an interface between an electrode and the layer after having passed through the layer by diffusion and convection.

24. A method according to claim 11, wherein a profile of use is a current profile or a power profile.

25. A method according to claim 12, wherein a profile of use is a current profile or a power profile.

36. A method according to claim 23, wherein a profile of use is a current profile or a power profile.

37. A method according to claim 11, wherein a profile of use is a charging profile of the system, a discharging profile of the system, or a profile corresponding to a series of charges and discharges.

38. A method according to claim 12, wherein a profile of use is a charging profile of the system, a discharging profile of the system, or a profile corresponding to a series of charges and discharges.

39. A method according to claim 13, wherein a profile of use is a charging profile of the system, a discharging profile of the system, or a profile corresponding to a series of charges and discharges.

40. A method according to claim 15, wherein the dynamic model of aging accounts for losses of electrical capacity and/or power of the system as a function of operational current, temperature, state of charge and depth of discharge factors.

41. A method according to claim 19, wherein the dynamic model of aging accounts for losses of electrical capacity and/or power of the system as a function of operational current, temperature, state of charge and depth of discharge factors.

42. A method according to claim 24, wherein the dynamic model of aging accounts for losses of electrical capacity and/or power of the system as a function of operational current, temperature, state of charge and depth of discharge factors.

43. A method according to claim 11, wherein the system for storing electrical power is a Li-ion, or Ni-MH, or Pb-acid battery or an ultracapacitor.

44. A method according to claim 12, wherein the system for storing electrical power is a Li-ion, or Ni-MH, or Pb-acid battery or an ultracapacitor.

45. A method according to claim 13, wherein the system for storing electrical power is a Li-ion, or Ni-MH, or Pb-acid battery or an ultracapacitor.

46. A method according to claim 15, wherein the system for storing electrical power is a Li-ion, or Ni-MH, or Pb-acid battery or an ultracapacitor.

47. A method according to claim 19, wherein the system for storing electrical power is a Li-ion, or Ni-MH, or Pb-acid battery or an ultracapacitor.

48. A method according to claim 24, wherein the system for storing electrical power is a Li-ion, or Ni-MH, or Pb-acid battery or an ultracapacitor.

49. A method according to claim 37, wherein the system for storing electrical power is a Li-ion, or Ni-MH, or Pb-acid battery or an ultracapacitor.

50. A method according to claim 11, wherein the aging indicator is a loss of electrical capacity or a loss of power.

51. A method according to claim 11, wherein the profile of use is modified until a minimal aging indicator is obtained by use of a constrained optimization algorithm.
